(19) United States
(12) Patent Application Publication
(10) Pub. No.: US 2024/0032371 A1
(43) Pub. Date: Jan. 25, 2024

(54) ORGANIC ELECTROLUMINESCENT DEVICES

(71) Applicant: Universal Display Corporation, Ewing, NJ (US)

(72) Inventors: Michael HACK, Carmel, CA (US); Michael Stuart WEAVER, Princeton, NJ (US); Lorne A. WHITEHEAD, Vancouver (CA)

(21) Appl. No.: 18/116,432

(22) Filed: Mar. 2, 2023

Related U.S. Application Data
(60) Provisional application No. 63/339,536, filed on May 9, 2022.

(51) Int. Cl. H10K 59/35

(52) U.S. Cl. CPC H10K 59/351

(57) ABSTRACT

Embodiments of the disclosed subject matter provide a device having an organic light emitting device (OLED) display comprising a plurality of metapixels. Each metapixel of the plurality of metapixels may have two or more sets of emissive regions that are configured to: (i) emit blue light that is a combination of light from the two or more sets of emissive regions that are configured to emit the blue light for that metapixel, and/or (ii) that are addressable by the same drive circuit. The metapixel may include more than one independently addressable sub-pixel configured to emit green light and more than one independently addressable sub-pixel configured to emit red light.

### CROSS-REFERENCE TO RELATED APPLICATIONS

This application claims priority to U.S. patent application Ser. No. 63/339,536, filed May 9, 2022, the entire contents of which are incorporated herein by reference.

### FIELD

The present invention relates to a metapixel design configured for full-color emission having one or more sets of addressable blue emissive regions and independently addressable red and green emissive regions, along with devices and techniques for fabricating the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more device selected from a consumer product, an electronic component module, and/or a lighting panel.

According to an embodiment, a device may be provided having an organic light emitting device (OLED) display including a plurality of metapixels. Each metapixel of the plurality of metapixels may have two or more sets of emissive regions that are configured to: (i) emit blue light that is a combination of light from the two or more sets of emissive regions that are configured to emit the blue light for that metapixel, and/or (ii) that are addressable by the same drive circuit. The metapixel may include more than one independently addressable sub-pixel configured to emit green light and more than one independently addressable sub-pixel configured to emit red light.

At least some of the emissive regions of each metapixel of the device may be configured to emit blue light, and may border neighboring metapixels in the OLED display. The at least some emissive regions of the each metapixel that border neighboring metapixels are adjacent to emissive regions of the neighboring metapixels that are configured to emit blue light.

A border perimeter of the emissive regions of each metapixel configured to emit blue light of the device may be longer than a border perimeter of any of the sub-pixels configured to emit green light or red light.

Each metapixel of the plurality of metapixels of the device may include more than one independently addressable sub-pixel configured to emit yellow light.

A size of the emissive regions of each metapixel configured to emit blue light of the device may be greater than 1.5 times, greater than 2 times, greater than 3 times, greater than 4 times, greater than 6 times, and/or greater than 8 times an emissive area of sub-pixels configured to emit green light or red light.

The emissive regions configured to emit blue light of the device may be greater than 15%, greater than 25%, greater than 50%, and/or greater than 75% of a region that surrounds the sub-pixels configured to emit green light or red light.

A border perimeter of the emissive regions of each metapixel of the device configured to emit blue light may be greater than 15%, greater than 25%, greater than 50%, and/or greater than 75% of the border perimeter.

Each metapixel of the device may include four or more sub-pixels to emit green light and four or more sub-pixels to emit red light.

Each metapixel of the device may include two or more sub-pixels to emit red light, and four or more sub-pixels to emit green light.

Each metapixel of the device may include two or more sub-pixels to emit green light, and four or more sub-pixels to emit red light.

Each metapixel of the device that includes the emissive regions configured to output blue light may be within a plane of blue sub-pixels, and the emissive regions may be deposited in two or more deposition operations.

Each metapixel of the device may include only two patterned OLED depositions that include a first emissive layer configured to emit blue light and a second emissive layer configured to emit yellow light. The device may further include at least one color altering layer configured to emit at least one of green light, and red light based on a conversion of yellow light from the second emissive layer.

Each metapixel is based on one unpatterned OLED deposition, and at least one selected from the group consisting of: color altering layers, and downconversion films are disposed on the unpatterned OLED deposition and are configured to produce light of other colors from the light output from the unpatterned OLED deposition.

According to an embodiment, a consumer electronic device may include a device having an organic light emitting device (OLED) display comprising a plurality of metapixels. Each metapixel of the plurality of metapixels may have two or more sets of emissive regions that are configured to: (i) emit blue light that is a combination of light from the two or more sets of emissive regions that are configured to emit the blue light for that metapixel, and/or (ii) that are addressable by the same drive circuit. The metapixel may include more than one independently addressable sub-pixel configured to emit green light and more than one independently addressable sub-pixel configured to emit red light.

The consumer electronic device may be at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows an example arrangement for a metapixel of a display based on four sets of red, yellow, and green sub-pixels, and having a high blue aperture ratio according to an embodiment of the disclosed subject matter.

FIG. 4 shows an example arrangement for a metapixel of a display having four sets of red and green sub-pixels, and having a high aperture ratio according to an embodiment of the disclosed subject matter.

FIG. 5 shows an example rectangular array of red pixels according to an embodiment of the disclosed subject matter.

FIG. 6 shows an example rectangular array of red pixels with the same average density of pixels as in FIG. 5, but with a regular perturbation that creates a higher spatial period component with a lower spatial frequency according to an embodiment of the disclosed subject matter.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

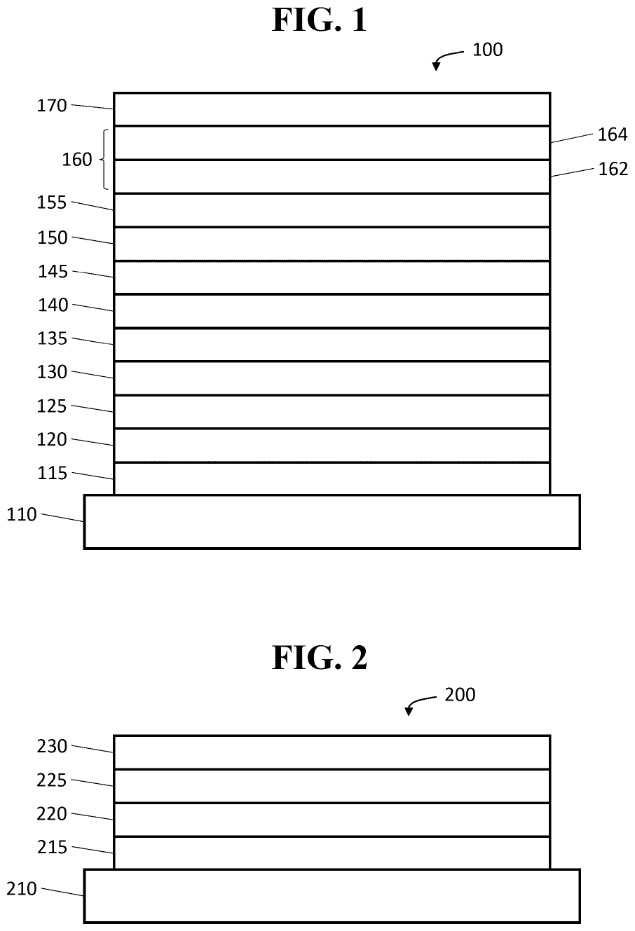

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution-based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e., P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

While prior systems and/or devices have focused on increasing blue sub-pixel fill factor to increase blue sub-pixel lifetime, in addition to sharing blue sub-pixels amongst multiple pixels, there has been little consideration to the impact of these arrangements on the visual performance of such pixels. In particular, if the blue sub-pixel is turned-off, it may be desirable to avoid having a display appear to have large “dead” (i.e., dark) regions and lower spatial resolution for red, green, and/or yellow sub-pixels.

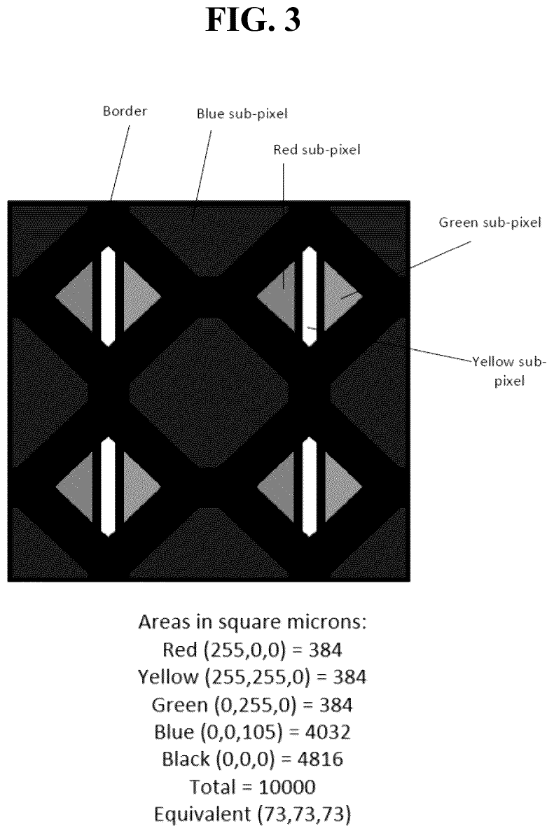

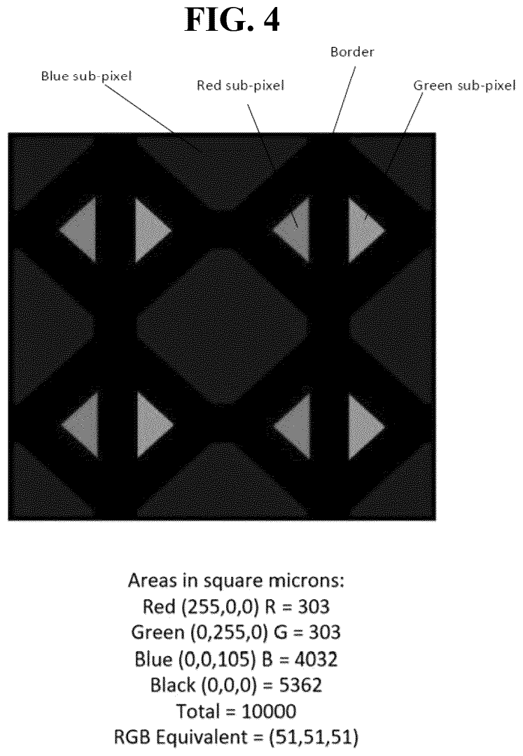

Embodiments of the disclosed subject matter, such as the examples shown in FIGS. 3-4, provide metapixel configurations for a display which may increase a blue fill-factor, but allows for an increase visual display quality and high resolution for red and/or green subpixels, and/or red, green, and/or yellow sub-pixels. As used throughout, a metapixel may be a region with one set of independently addressable blue emissive regions (i.e., sub-pixels) with more than one independently addressable red and/or green sub-pixels, and in some instances red, green, and/or yellow sub-pixels that may be configured for full color emission.

Embodiments of the disclosed subject matter may increase the blue fill-factor to extend blue sub-pixel lifetime, and may include display arrangements with increased visual quality.

FIGS. 3-4 show an example pixel arrangement based on a 500 dpi (dots per inch) RGBY (red, green blue, and yellow) color sub-pixel display, with a 100 μm×100 μm metapixel having 50 μm between the red, green, and yellow sub-pixels. In the example arrangements, a 10 μm alignment tolerance may be selected between different color emissive regions to avoid emissive regions being impacted by emitters spilling over from one color emissive region to another (i.e., having overlapping emitters of different color emissive regions). In some embodiments, a blue-yellow emissive layer (EML) arrangement may be used, and there may be a 10 μm spacing between a blue emissive region and a yellow emissive region, where red and/or green light may be produced using a color altering layer. For example, microcavities, color filters, and/or down conversation media such as quantum dots or the like may provide color altering of light emitted from at least one of the emissive regions.

FIG. 3 shows an example arrangement for a metapixel of a display based on four sets of red, yellow, and green sub-pixels, with a predetermined very high blue aperture ratio. In this example arrangement, two yellow and blue emissive layers may be deposited, with a 10 μm design rule (e.g., a border) between these active areas. The example shown in FIG. 3 may be a 500 dpi display with 100 μm×100 μm metapixel, with 50 μm spacing between the red, yellow, and green sub-pixels.

FIG. 4 shows an example three color sub-pixel arrangement with 10 μm spacing between each of the three emissive colors. As shown in FIG. 4, the arrangement may include four sets of red sub-pixels, green sub-pixels, and blue sub-pixels. The sub-pixels may be side-by-side sub-pixels. In this example arrangement, there may be three emitter depositions for the red, green, and blue sub-pixels.

Color displays may include a regularly repeating pattern of at least three types (e.g., three types, four types, or the like) of light emitting zones. These emissive areas may be referred to as red, yellow, green, and/or blue emissive areas to approximately describe the spectral power distribution of the light emitted by such areas. Such terms may be used throughout, but this is merely for convenience and does not imply that the following new design concepts are limited to systems with just those primaries or any particular choice of spectral power distributions.

Embodiments of the disclosed subject matter provide a pixel array where individual pixels may be invisible to a viewer when the display is displaying one or more images at an intended viewing distance. In this context, “invisible” means that the pixel pattern may not be noticeable to a viewer, and the pixel pattern may not detract from perceived image quality.

It should be noted that many images may have intensely colored regions in which only one, only two, or the like of the pixel types may be emitting. Example pixel arrangements of the disclosed subject matter may be included in displays to produce such images.

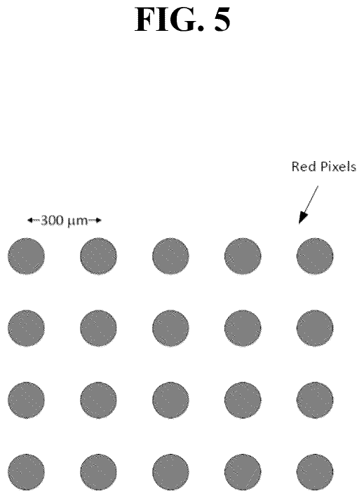

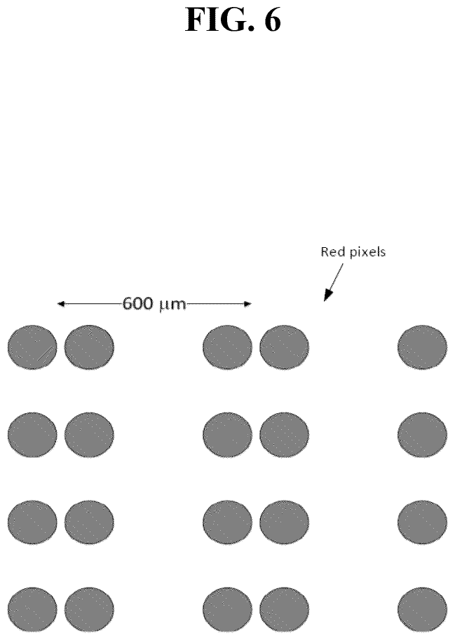

In general, one of the key predictors of visibility is the angular frequency distribution of the pattern at the planned viewing distance. For any given pattern, at a given viewing distance, there may be a range of spatial frequencies associated with it, which can be obtained by 2D Fourier analysis of the pattern. The visibility of a given spatial frequency component may have a strong inverse relationship with its frequency. A good predictor of the visibility of a pixel pattern may be its minimum spatial frequency component, which may correspond to its maximum spatial period. These concepts are discussed below in connection with FIGS. 5-6.

FIG. 5 shows a rectangular array for a given pixel type. In the example shown in FIG. 5, the rectangular array may include an arrangement of red pixels. The lowest spatial frequency may be inversely proportional to the spacing. In the example shown in FIG. 5, the spatial frequency may be 300 μm.

FIG. 6 show an example pattern that has the same overall spatial density of red pixels as in FIG. 5, but with a periodic displacement within the array. The arrangement of the red pixels in FIG. 6 has a regular perturbation that creates a higher spatial period component and a lower spatial frequency component, which is more likely to be visible to a viewer of a display than the arrangement shown in FIG. 5.

As shown in the example of FIGS. 5-6, the number density of the pixels alone may not predict the visibility of the pixel pattern, because some patterns may have numerous different spatial frequency components. The components with the largest spatial period and have the lowest spatial frequency may be the dominant cause of pixel visibility in a display. The intensity of a given spatial frequency component may be important. The human eye has a much higher sensitivity to red, yellow, and green patterns, because they are primarily detected via the L and M cones in the retina, whereas blue patterns are detected by the far less numerous S cones.

Embodiments of the disclosed subject matter satisfy the practical need for a much larger relative area for the blue sub-pixels, which may reduce the current density in the blue sub-pixel and extend the lifetime of the blue sub-pixels.

In previous designs, if the B area fraction increases (i.e., the emissive area that emits blue light), this compresses the L (left) and R (right) pixels closer together (e.g., red and green pixels), creating a reduced spatial frequency component within the overall pattern of L and M cones. Among other advantages, embodiments of the disclosed subject matter may maintain a regular square array for the red (R) and green (G) (and, in some embodiments, yellow (Y)) sub-pixels, based on the layout of the B areas.

Embodiments of the disclosed subject matter may include a device having an organic light emitting device (OLED) display having a plurality of metapixels. Such as shown in FIGS. 3-4, each metapixel of the plurality of metapixels may have two or more sets of emissive regions that are configured to: (i) emit blue light that is a combination of light from the two or more sets of emissive regions that are configured to emit the blue light for that metapixel, and/or (ii) that are addressable by the same drive circuit and/or controller. The metapixel may include more than one independently addressable sub-pixel configured to emit green light and more than one independently addressable sub-pixel configured to emit red light, such as shown in FIGS. 3-4. FIG. 3 shows an example with four sets of red, green, and yellow sub-pixels, and FIG. 4 shows an example with four sets of red and green sub-pixels.

At least some of the emissive regions of each metapixel of the device may be configured to emit blue light border neighboring metapixels in the OLED display. Two metapixels may have blue emissive regions next to each other (with no other color in between), but the emissive regions that emit blue light in each metapixel may be driven independently from the emissive regions that emit blue light in the neighboring metapixel. The at least some emissive regions of the each metapixel that border neighboring metapixels may be adjacent to emissive regions of the neighboring metapixels that are configured to emit blue light.

A border perimeter of the emissive regions of each metapixel configured to emit blue light of the device may be longer than a border perimeter of any of the sub-pixels configured to emit green light or red light. Examples of the border perimeter are shown in FIGS. 3-4.

Each metapixel of the plurality of metapixels of the device may include more than one independently addressable sub-pixel configured to emit yellow light. For example, the metapixels shown in FIG. 3 may include independently addressable sub-pixels to emit yellow light.

A size of the emissive regions of each metapixel configured to emit blue light of the device may be greater than 1.5 times, greater than 2 times, greater than 3 time, greater than 4 times, greater than 6 times, and/or greater than 8 times an emissive area of sub-pixels configured to emit green light or red light. In some embodiments, the emissive regions configured to emit blue light of the device may be greater than 15%, greater than 25%, greater than 50%, and/or greater than 75% of a region that surrounds the sub-pixels configured to emit green light or red light.

A border perimeter of the emissive regions of each metapixel of the device configured to emit blue light may be greater than 15%, greater than 25%, greater than 50%, and/or greater than 75% of an overall metapixel border perimeter. Examples of the border perimeter for metapixels are shown in FIGS. 3-4.

In some embodiments, each metapixel of the device may include four or more sub-pixels to emit green light and four or more sub-pixels to emit red light. For example, although FIGS. 3-4 show four sub-pixels to emit green light and four sub-pixels to emit red light, but more than four sub-pixels to emit green light and red light may be used. In some embodiments, each metapixel may include two or more sub-pixels to emit red light, and four or more sub-pixels to emit green light. In some embodiments, each metapixel may include two or more sub-pixels to emit green light, and four or more sub-pixels to emit red light.

Each metapixel of the device that includes the emissive regions configured to output blue light may be within a plane of blue sub-pixels, and the emissive regions may be deposited in two or more deposition operations.

In some embodiments, each metapixel of the device may include only two patterned OLED depositions that include a first emissive layer configured to emit blue light and a second emissive layer configured to emit yellow light. The device may further include at least one color altering layer configured to emit green light and/or red light based on a conversion of yellow light from the second emissive layer. In some embodiments, the color altering layer may be disposed outside of the OLED device, such as above or below an electrode of the OLED device.

Each metapixel may be based on one unpatterned OLED deposition, along with color altering layers and/or downconversion films that are disposed on the unpatterned OLED deposition. The color altering layers may be configured to produce light of other colors from the light output from the unpatterned OLED deposition. As used throughout, an unpatterned OLED deposition may include patterning over a final device and/or display, but may not be patterned at a predetermined resolution (e.g., a high resolution).

In some embodiments, a consumer electronic device may include a device having an organic light emitting device (OLED) display having a plurality of metapixels. Each metapixel of the plurality of metapixels may have two or more sets of emissive regions that are configured to: (i) emit blue light that is a combination of light from the two or more sets of emissive regions that are configured to emit the blue light for that metapixel, and/or (ii) that are addressable by the same drive circuit. The metapixel may include more than one independently addressable sub-pixel configured to emit green light and more than one independently addressable sub-pixel configured to emit red light.

The consumer electronic device may be a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

We claim:

1. A device comprising:
an organic light emitting device (OLED) display comprising a plurality of metapixels, each metapixel of the plurality of metapixels comprising:
two or more sets of emissive regions that are configured by at least one selected from the group consisting of:
(i) to emit blue light that is a combination of light from the two or more sets of emissive regions that are configured to emit the blue light for that metapixel, and
(ii) that are addressable by the same drive circuit, and
wherein the metapixel includes more than one independently addressable sub-pixel configured to emit green light and more than one independently addressable sub-pixel configured to emit red light.

2. The device of claim 1, wherein at least some of the emissive regions of each metapixel are configured to emit blue light, and border neighboring metapixels in the OLED display.

3. The device of claim 2, wherein the at least some emissive regions of the each metapixel that border neighboring metapixels are adjacent to emissive regions of the neighboring metapixels that are configured to emit blue light.

4. The device of claim 1, wherein a border perimeter of the emissive regions of each metapixel configured to emit blue light is longer than a border perimeter of any of the sub-pixels configured to emit green light or red light.

5. The device of claim 1, wherein each metapixel of the plurality of metapixels further comprises:
more than one independently addressable sub-pixel configured to emit yellow light.

6. The device of claim 1, wherein a size of the emissive regions of each metapixel configured to emit blue light are at least one selected from the group consisting of: greater than 1.5 times, greater than 2 times, greater than 3 times, greater than 4 times, greater than 6 times, and greater than 8 times an emissive area of sub-pixels configured to emit green light or red light.

7. The device of claim 1, wherein the emissive regions configured to emit blue light are at least one selected from the group consisting of: greater than 15%, greater than 25%, greater than 50%, and greater than 75% of a region that surrounds the sub-pixels configured to emit green light or red light.

8. The device of claim 1, where a border perimeter of the emissive regions of each metapixel configured to emit blue light are at least one selected from the group consisting of: greater than 15%, greater than 25%, greater than 50%, and greater than 75% of the border perimeter.

9. The device of claim 1, wherein each metapixel comprises four or more sub-pixels to emit green light and four or more sub-pixels to emit red light.

10. The device of claim 1, wherein each metapixel comprises two or more sub-pixels to emit red light, and four or more sub-pixels to emit green light.

11. The device of claim 1, wherein each metapixel comprises two or more sub-pixels to emit green light, and four or more sub-pixels to emit red light.

12. The device of claim 1, wherein each metapixel that includes the emissive regions configured to output blue light are within a plane of blue sub-pixels, and
wherein the emissive regions are deposited in two or more deposition operations.

13. The device of claim 1, wherein each metapixel includes only two patterned OLED depositions that include a first emissive layer configured to emit blue light and a second emissive layer configured to emit yellow light,
wherein the device further comprises at least one color altering layer configured to emit at least one of green light, and red light based on a conversion of yellow light from the second emissive layer.

14. The device of claim 1, where each metapixel is based on one unpatterned OLED deposition, and at least one selected from the group consisting of: color altering layers, and downconversion films are disposed on the unpatterned OLED deposition and are configured to produce light of other colors from the light output from the unpatterned OLED deposition.

15. A consumer electronic device comprising:
a device comprising:
an organic light emitting device (OLED) display comprising a plurality of metapixels, each metapixel of the plurality of metapixels comprising:
two or more sets of emissive regions that are configured by at least one selected from the group consisting of:
(i) to emit blue light that is a combination of light from the two or more sets of emissive regions that are configured to emit the blue light for the metapixel, and
(ii) that are addressable by the same drive circuit, and
wherein the metapixel includes more than one independently addressable sub-pixel configured to emit green light and more than one independently addressable sub-pixel configured to emit red light.

16. The consumer electronic device of claim 13, wherein the device is at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign.
